(19) United States
(12) Patent Application Publication
(10) Pub. No.: US 2023/0378928 A1
(43) Pub. Date: Nov. 23, 2023

(54) Assemblies Including an Acoustic Resonator Device and Methods of Forming

(71) Applicant: Qorvo Biotechnologies LLC, Plymouth, MN (US)

(72) Inventors: Chuck Edward Carpenter, Orlando, FL (US); Rio Rivas, Bend, OR (US); Buu Quoc Diep, Murphy, TX (US)

(21) Appl. No.: 18/248,128

(22) PCT Filed: Oct. 29, 2021
(86) PCT No.: PCT/US2021/057240

§ 371 Date: Apr. 6, 2023

Related U.S. Application Data
(60) Provisional application No. 63/107,136, filed on Oct. 29, 2020.

(51) Int. Cl. H03H 9/02; H03H 9/17; H03H 9/10

(52) U.S. Cl. CPC H03H 9/02015; H03H 9/172; H03H 9/1014

(57) ABSTRACT

Assemblies including a bulk acoustic wave acoustic sensor die having a first and an opposing second major surface, the die including a piezoelectric structure, a first and a second electrode electrically connected to the piezoelectric structure, and an active surface on the first major surface of the die; a printed circuit board (PCB), the PCB having a first major surface and an opposing second major surface and including a slot spanning from the first major surface to the second major surface through the PCB; a first bond electrically and mechanically connecting the die to the PCB; and a second bond electrically and mechanically connecting the die to the PCB, wherein the first and the second bonds are located on either side of the slot through the PCB and the active surface of the die is above the slot in the PCB.

### CROSS-REFERENCE TO RELATED APPLICATIONS

This application is a non-provisional of U.S. provisional patent application U.S. Application Ser. No. 63/107,136 filed Oct. 29, 2020, the disclosure of which is hereby incorporated herein by reference in its entirety.

### TECHNICAL FIELD

This disclosure generally relates to methods of forming assemblies that include an acoustic wave resonator device and methods of forming such assemblies.

### SUMMARY

Previous fabrication methods utilized flip chip mounting of dies containing the acoustic wave resonators using flux and soldering. Because of the use of flux, the die would have to be washed after bonding. Additionally, the washing step required use of a wash fixture in order to minimize the possibility that the die to printed circuit board bond would be disrupted and fail during washing. Additionally, the wash step was not entirely successful at removing all contamination from the active die surface after flux and soldering steps.

The techniques of this disclosure generally relate to methods of fabricating devices that include bulk acoustic wave resonator sensors that may be more effectively and easily electrically connected to a printed circuit board. Additionally, systems formed using such methods are also disclosed and are suitable for biosensing or biochemical sensing applications. Such methods and devices include forming bonds between electrical connection bumps on the acoustic wave resonator containing die and the electrical connection pads on a printed circuit board (PCB) using thermosonic bonding. Such methods avoid the use of flux, solder, and concomitant washing steps that go along with their use after die attachment, which can lead to problematic contamination with final products.

Disclosed herein are methods of bonding a bulk acoustic wave sensor die and a printed circuit board, the method comprising: obtaining a die, the die having a first major surface and an opposing second major surface, the die comprising a bulk acoustic wave sensor that comprises a piezoelectric structure electrically connected to a first and a second electrode, the first and the second electrode electrically connected to a first and a second electrical connection bump on the first major surface of the die; obtaining a printed circuit board (PCB), the PCB having a first major surface and an opposing second major surface, the PCB having a slot that spans from the first major surface to the second major surface of the PCB, the first major surface having a first and a second connection pads adjacent to the slot through the PCB; aligning the first and the second electrical connection bumps of the die with the first and the second connection pads respectively on the PCB such that the first surface of the die is above the slot in the PCB; contacting the first and the second electrical connection bumps of the die with the first and the second connection pads of the PCB respectively; heating the die, the PCB, or both; applying a force to the die, the force being applied in the direction of the PCB; and applying ultrasonic energy to the die to bond the first and the second electrical connection bumps of the die with the first and the second connection pads of the PCB respectively.

Also disclosed are methods, wherein the first and the second electrical connection bumps of the die comprise gold. Also disclosed are methods, wherein the first and the second electrical connection bumps of the die are electrically connected to first and second die electrical connection pads that are electrically connected to the first and second electrodes of the die respectively. Also disclosed are methods, wherein the first and the second connection pads of the PCB comprise gold. Also disclosed are methods further comprising plasma treating the PCB, the die, or a combination thereof prior to contacting the first and the second electrical connection bumps of the die with the first and the second connection pads respectively on the PCB. Also disclosed are methods further comprising encapsulating the bonded first and second electrical connection bumps of the die and the first and second connection pads of the PCB respectively with underfilling dielectric material to provide electrical isolation. Also disclosed are methods, wherein the first and the second electrical connection bumps of the die are bonded to the first and the second connection pads respectively on the PCB without the use of flux. Also disclosed are methods, wherein the first and the second electrical connection bumps of the die are bonded to the first and the second connection pads respectively on the PCB without the use of solder. Also disclosed are methods, wherein the first and the second electrical connection bumps of the die are bonded to the first and the second connection pads respectively on the PCB without the need for an aqueous wash and rinse after bonding. Also disclosed are methods, wherein the first major surface of the die has an active surface thereon. Also disclosed are methods, wherein the die and the PCB are aligned such that the active surface of the die is above the slot in the PCB.

Also disclosed are assemblies comprising: a bulk acoustic wave acoustic sensor die having a first and an opposing second major surface, the die comprising a piezoelectric structure, a first and a second electrode electrically connected to the piezoelectric structure, and an active surface on the first major surface of the die; a printed circuit board (PCB), the PCB having a first major surface and an opposing second major surface and comprising: a slot spanning from the first major surface to the second major surface through the PCB; a first bond electrically and mechanically connecting the die to the PCB; and a second bond electrically and mechanically connecting the die to the PCB, wherein the first and the second bonds are located on either side of the slot through the PCB and the active surface of the die is above the slot in the PCB.

Also disclosed are assemblies, wherein the first and the second bonds were formed by fusing a first and a second electrical connection bump on the first major surface of the die with first and second electrical connection pads on the first major surface of the PCB. Also disclosed are assemblies, wherein the first and the second electrodes are electrically and mechanically connected to the first and the second bonds respectively. Also disclosed are assemblies, wherein the PCB further comprises a metallic underlayer mechanically and electrically connected to the first and the second bonds respectively. Also disclosed are assemblies, wherein the first and the second electrical connection bumps on the first major surface of the die comprise gold. Also disclosed are assemblies further comprising first and second die electrical connection pads wherein the first and second die electrical connection pads are electrically connected to the first and the second electrical connection bumps and the first and second die electrical connection pads comprise gold. Also disclosed are assemblies, wherein the first and second die electrical connection bumps are placed on the first and second electrical connection pads using a wire bonding process. Also disclosed are assemblies, wherein first and second electrical connection pads on the PCB are formed using electroless nickel immersion/immersion gold (ENIG), electroless nickel electroless palladium immersion gold (ENEPIG) or electroplated gold. Also disclosed are assemblies, wherein the first and the second bonds are comprised of gold. Also disclosed are assemblies, wherein the first and the second bonds do not include any flux, solder, or combinations thereof. Also disclosed are assemblies further comprising underfill regions that encapsulate the first and second bonds with dielectric material to provide electrical isolation. Also disclosed are assemblies, wherein the dielectric material comprises a polymeric material. Also disclosed are assemblies, wherein the polymeric material comprises a polyimide, an epoxy, or combinations thereof.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF DRAWINGS

The accompanying drawing figures incorporated in and forming part of this specification illustrate several aspects of this disclosure and together with the description serve to explain various principles of this disclosure.

FIGS. 1A to 1F show a bulk acoustic wave resonator containing device and printed circuit board being subjected to disclosed methods.

FIG. 2 shows a bulk acoustic wave resonator containing device and printed circuit board with optional underfill regions.

FIGS. 3A and 3B show a printed circuit board with a bonded bulk acoustic wave resonator containing device (FIG. 3A) and a closer view of the region where the bonding takes place (FIG. 3B).

The figures are not necessarily to scale. Like numbers used in the figures refer to like components. However, it will be understood that the use of a number to refer to a component in a figure is not intended to limit the component in another figure labeled with the same number.

### DETAILED DESCRIPTION

In the following detailed description several specific embodiments of compounds, compositions, apparatuses, systems and methods are disclosed. It is to be understood that other embodiments are contemplated and may be made without departing from the scope or spirit of the present disclosure. The following detailed description, therefore, is not to be taken in a limiting sense.

It will be understood that, although the terms first, second, etc. may be used herein to describe various elements these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

Relative terms such as “below” or “above” or “upper” or “lower” or “top” or “bottom” or “horizontal” or “vertical” may be used hereinto describe a relationship of one element, layer, or region to another element, layer, or region as illustrated in the Figures. It will be understood that these terms and those discussed above are intended to encompass different orientations of the device in addition to the orientation of the Figures.

The terminology used here is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “include,” and/or “including” when used herein specify the presence of stated features, integers, steps, operations, elements, and/or components, but do not preclude the presence or addition of one or more other features, integers, steps, operations, elements, components, and/or groups thereof. As used herein, the terms “proximate” and “adjacent′ as applied to a specified layer or element refer to a state of being close or near to another layer or element and encompass the possible presence of one or more intervening layers or elements to be directly on or directly in contact with the other layer or element unless specified to the contrary herein.

The term “substrate” is used here to refer to a material onto which a seed layer or a bulk layer may be deposited. The substrate may be, for example, a wafer, or may be a part of a resonator device complex or wafer, which may also include other components, such as an electrode structure arranged over at least a portion of the substrate. A seed layer is not considered to be “a substrate” in the embodiments of this disclosure.

The term “substantially” as used here has the same meaning as “nearly completely,” and can be understood to modify the term that follows by at least about 90%, at least about 95%, or at least about 98%.

The terms “parallel” and “substantially parallel” with regard to the crystals refer to the directionality of the crystals. Crystals that are substantially parallel not only have the same or similar c-axis tilt but also point in the same or similar direction.

The term “about” is used here in conjunction with numeric values to include normal variations in measurements as expected by persons skilled in the art and is understood have the same meaning as “approximately” and to cover a typical margin of error, such as ±5% of the stated value.

All scientific and technical terms used herein have meanings commonly used in the art unless otherwise specified. The definitions provided herein are to facilitate understanding of certain terms used frequently herein and are not meant to limit the scope of the present disclosure.

As used here, the singular forms “a”, “an”, and “the” encompass embodiments having plural referents, unless the content clearly dictates otherwise.

As used here, the term “or” is generally employed in its sense including “and/or” unless the content clearly dictates otherwise. The term “and/or” means one or all of the listed elements or a combination of any two or more of the listed elements.

As used here, “have”, “having”, “include”, “including”, “comprise”, “comprising” or the like are used in their open-ended sense, and generally mean “including, but not limited to.” It will be understood that “consisting essentially of,” “consisting of,” and the like are subsumed in “comprising” and the like. As used herein, “consisting essentially of,” as it relates to a composition, product, method or the like, means that the components of the composition, product, method or the like are limited to the enumerated components and any other components that do not materially affect the basic and novel characteristic(s) of the composition, product, method or the like.

The words “preferred” and “preferably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure, including the claims.

The recitations of numerical ranges by endpoints include all numbers subsumed within that range (e.g., 1 to 5 includes 1, 1.5, 2, 2.75, 3, 3.80, 4, 5, etc. or 10 or less includes 10, 9.4, 7.6, 5, 4.3, 2.9, 1.62, 0.3, etc.). Where a range of values is “up to” a particular value, that value is included within the range.

Disclosed methods and assemblies or systems formed herein include use of a device or a die. A die, as used herein, is a small block of semiconducting material on which a given functional circuit including a bulk acoustic wave (BAW) is fabricated. Typically, integrated circuits such as those disclosed and utilized herein, are produced in large batches on a single wafer of electronic-grade silicon (EGS) or other semiconductor material (such as GaAs for example) through processes such as photolithography. The wafer is cut (diced) into many pieces, each containing one copy of the circuit. Each of these pieces is referred to as a die.

Disclosed and utilized dies herein include a bulk acoustic wave resonator that includes a piezoelectric crystal resonator. In the case of a piezoelectric crystal resonator, an acoustic wave may embody either a bulk acoustic wave (BAW) propagating through the interior of a substrate, or a surface acoustic wave (SAW) propagating on the surface of the substrate, SAW devices involve transduction of acoustic waves (commonly including two-dimensional Rayleigh waves) utilizing interdigital transducers along the surface of a piezoelectric material, with the waves being confined to a penetration depth of about one wavelength. In a BAW device, three wave modes can propagate, namely, one longitudinal mode (embodying shear waves, also called compressional/extensional waves), and two shear modes (embodying shear waves, also called transverse waves) with longitudinal and shear modes respectively identifying vibrations where particle motion is parallel to or perpendicular to the direction of wave propagation. The longitudinal mode is characterized by compression and elongation in the direction of wave propagation, whereas the shear modes consist of motion perpendicular to the direction of the propagation. Longitudinal and shear modes consist of motion perpendicular to the direction of the action on the longitudinal direction.

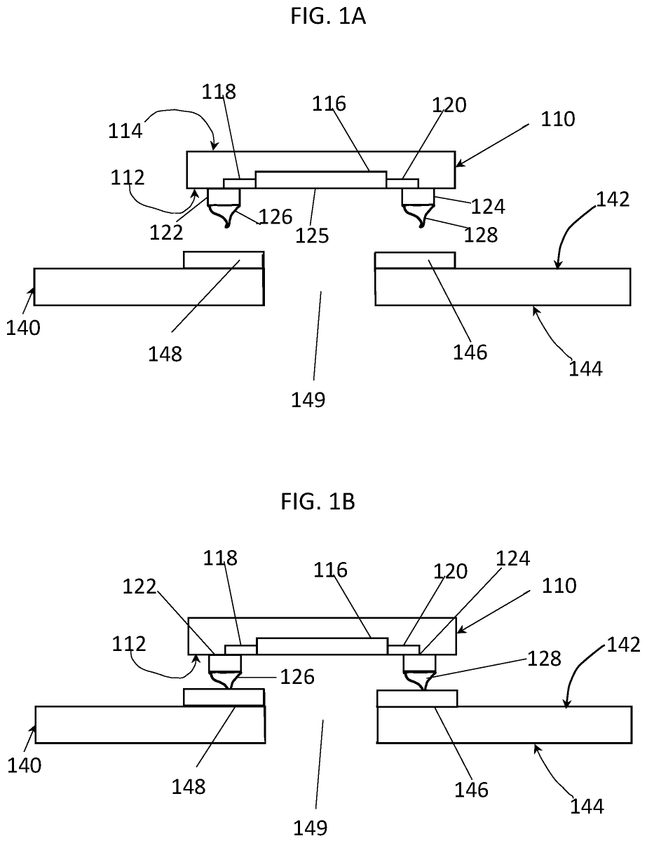

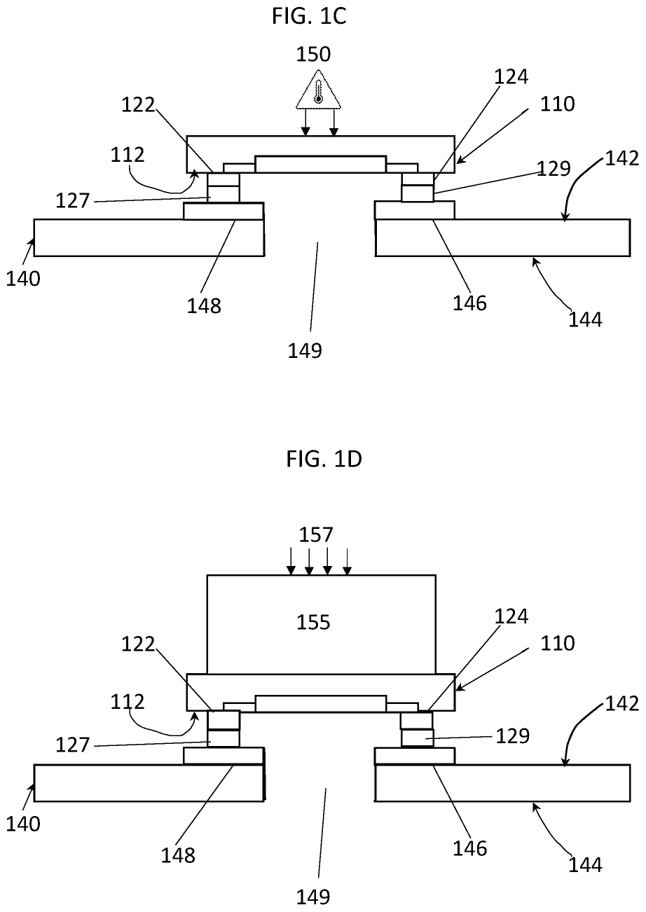

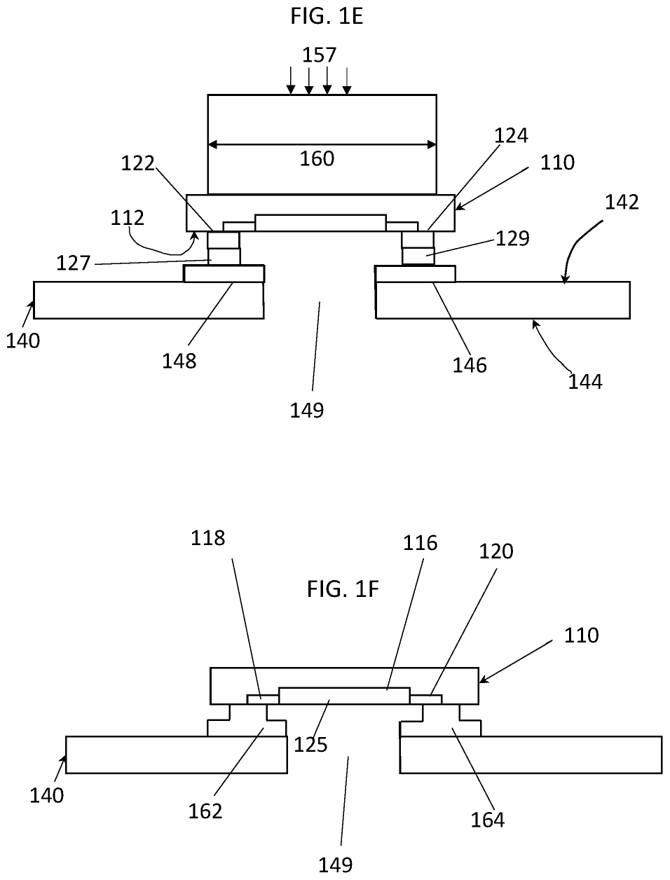

The present disclosure relates to methods of forming assemblies and the assemblies formed thereby that include a bulk acoustic wave (BAW) resonator on a die. In some embodiments, the BAW can more specifically be a thin film bulk acoustic resonator (TFBAR). An illustrative die 110 is depicted in FIG. 1A. The die 110 includes a first major surface 112 and an opposing second major surface 114. The die 110 includes a first conductive material forming a first electrode 118, a piezoelectric structure 116 (that may or may not contain more than one layer of which one is a piezoelectric layer) that is part of a BAW resonator, and a second conductive material 120 forming a second electrode with the piezoelectric structure 116 located between the two electrodes. The first electrode 118, the second electrode 120, or both may extend in either direction from that shown in FIGS. 1A and 1n some embodiments can cover at least a portion of the piezoelectric structure 116. The first electrode 118 is electrically connected to a first die electrical connection pad 122 and the second electrode 120 is electrically connected to a second die electrical connection pad 124. The first die electrical connection pad 122 and the second die electrical connection pad 124 are located on the first face 112 of the die 110. In contact with the first die electrical connection pad 122 and the second die electrical connection pad 124 are first die bump 126 and second die bump 128 respectively. The die also includes an active surface 125 that can ultimately be utilized part of a larger system to detect and quantify the amount of analyte in a sample. Although the structure depicted in FIG. 1A shows that the surface of the piezoelectric layer 116 itself forms the active surface 125, it should be noted that additional layers can cover at least a portion of the piezoelectric layer 116 to form the active surface 125. The first and second die electrical connection pads 122 and 124 can be formed by physical vapor deposition (PVD) or sputtering for example. The first and second die bumps 126 and 128 are in contact with the first and second die electrical connection pads 122 and 124 respectively and can be formed by wire bonding a short gold wire to the first and second die electrical connection pads 122 and 124.

In accordance with aspects of the present disclosure, the piezoelectric structure as well as other elements or portions on the device (or the PCB to be discussed below) can be fabricated using micro-electro-mechanical systems (MEMS) techniques suitable to produce microscale features suitable for biosensors, functionalization materials (e.g., specific binding materials). Deposition techniques such as atomic layer deposition (ALD), chemical vapor deposition (CVD), or physical vapor deposition (PVD) may be used in conjunction with one or more masks (e.g., photolithographic masks) to pattern various portions of the structures being formed.

Also depicted in FIG. 1A is the printed circuit board (PCB). The PCB 140 has a first major surface 142 and an opposing second major surface 144. The PCB generally provides a platform for the die 110, electronics to make the structures on the die function as intended, portions of a fluid pathway, and other optional structures and can be manufactured from materials suitable for printed circuit boards (PCBs), such as rigid laminated PCB materials including polyimides and epoxies, or flexible materials, such as polyimide, polyethylene terephthalate (PET), and combinations thereof. The PCB also includes a first PCB connection pad 146 and a second PCB connection pad on the first major surface 148. Located between the first PCB connection pad 146 and the second PCB connection pad 148 is a slot 149. The slot 149 can ultimately become part of a fluid pathway. In one embodiment, the sensor platform is manufactured from high dielectric PCB material available from Rogers Corp. in Chandler, AZ.

Initial steps include obtaining the die 110 and the PCB 140. These steps can include purchasing either or both of the components, fabricating either or both of the components, or combinations thereof. There is no particular order in which the steps of obtaining the two need be accomplished and such can occur substantially simultaneously in some embodiments.

Another step in disclosed methods includes aligning the die and the PCB. In some embodiments, the die and the PCB are positioned such that the first and the second electrical connection bumps of the die are aligned with the first and the second connection pads respectively on the PCB. Generally, the die and the PCB are aligned such that the first surface of the die is above the slot in the PCB. More specifically, the die and the PCB are aligned such that the active surface 125 of the die is above the slot 149 in the PCB The step of aligning can be accomplished using known techniques, processes, machines, tools, or any combination thereof as would be known to one of skill in the art having read this disclosure. In some embodiments, optical tools including for examples lasers and sensors can be utilized to assist in aligning the die and the PCB. For example, a vision system that shows the PCB connection pad and die bump alignment may be utilized along with a means to make fine adjustments to achieve correct alignment. Use of a microscope with an appropriate lighting system may be helpful in process observation and optimization.

Another step in disclosed methods includes contacting the first and the second electrical connection bumps of the die with the first and the second connection pads respectively on the PCB. In some embodiments this can include lowering the die to the PCB, raising the PCB to the die, or combinations thereof. The step of contacting can be accomplished using known techniques, processes, machines, tools, or any combination thereof as would be known to one of skill in the art having read this disclosure. In some embodiments, hydraulic or pneumatic powered platforms or other devices including for examples computer-controlled devices or structures can be utilized in contacting the die and the PCB. A holder that can present waffle or gel packs can be used for die pick-up, alignment, holding, application of force, etc., may be utilized. A die bonding collet with vacuum may be used to pick die and securely hold it during the bonding process. Because of the ultrasonic motion, a four-sided collet with an inverted pyramid shaped opening may be useful to accurately capture the die. The pick and place mechanism may be capable of picking the die with the collet and placing it accurately while applying a bond load that may be variable.

FIG. 1B shows the die 110 and the PCB 140 once they are in contact.

Disclosed methods include the use of thermsonic bonding. Thermosonic bonding can include steps of heating one or both of the members to be bonded, applying pressure or force to one or both of the members to be bonded, applying ultrasonic motion to one or both of the members to be bonded, or combinations thereof. In some embodiments, the various discrete steps that make up thermosonic bonding can be carried out sequentially, substantially at the same time, or in some other fashion.

In some embodiments, a step of heating the die to at least 150° C. may be utilized. A heated stage with mechanical clamps can be used to firmly hold the substrate in place can be utilized. A stage capable of heating to 150° C. or above may be utilized. Additional spot heating may be utilized when using substrates that cannot transfer heat well to the bonding area. In this instance, a spot heating system can deliver topside heating and raise the bonding surface to the desired temperature. A heater attached to the bonding tool may also be used, but these can tend to interfere with the ultrasonic action. In some embodiments, this step may include heating the PCB as well as the die. In some embodiments, the die, the PCB, or a combination thereof may be heated to at least 150° C. In some embodiments, the die the PCB, or a combination thereof may be heated to at least 150° C., at least 200° C., at least 210° C., or at least 225° C. In some embodiments, the die may be heated to at least 150° C., at least 200° C., at least 210° C., or at least 225° C. In some embodiments, the PCB may be heated to at least 150° C., at least 200° C., at least 210° C., or at least 225° C. In some embodiments, a combination of the die and the PCB may be heated to at least 150° C., at least 200° C., at least 210° C., or at least 225° C. In some embodiments, the PCB may be kept at a lower temperature than the die. For example, the PCB may be at least 30° C., at least 50° C., or at about 75° C. Such temperatures of the PCB may be monitored and maintained while applying ultrasonic energy to the die.

FIG. 1C shows the die 110 and the PCB after an example of a step of applying heat, specifically, after heat (depicted by 150) is applied to the die 110. The assemblies beginning in FIG. 1C and continuing to FIG. 1E show that the first and second die connection bumps 126 and 128 have been re-flowed to form first and second die connections 127 and 129 respectively. The transformation from the first and second die connection bumps 126 to the first and second die connections 127 and 129 respectively takes place via the application of heat, pressure, or a combination thereof.

Disclosed embodiments utilize a step of applying a force to one or both the die and the PCB. In some embodiments, a force can be applied to the die (forcing the die towards the PCB), a force can be applied to the PCB (forcing the PCB towards the die), or a force can be applied to both the die and the PCB (forcing the die and the PCB towards each other). In some embodiments, the force can be measured as a function of how much force is applied per electrical connection bump, per electrical connection pad or per electrical connection bump/electrical connection pad. In some embodiments, the force per electrical connection bump or per electrical connection pad can be from 20 to 80 grams per electrical connection bump or per electrical connection pad.

FIG. 1D shows the die 110 and the PCB 140 as force 157 is being applied to, in this illustrative embodiment, the die 110 via a block 155. The block 155 can be part of a larger system or tool designed to apply force and control the level of force being applied, for example. For example, it could be part of a thermosonic bonding tool or machine.

Disclosed embodiments also apply ultrasonic energy to the die to bond the die to the PCB, or more specifically to bond the first and the second electrical connections 127 and 129, which were formed from the first and second die connection bumps 124 and 126 of the die with the first and the second connection pads of the PCB respectively. In some embodiments, the ultrasonic motion is in a direction that is orthogonal to the direction of the force being applied to the die, the PCB, or the combination thereof. An ultrasonic generator and transducer capable of applying ultrasonic motion may be utilized. In some embodiments, an ultrasonic generator and transducer capable of applying ultrasonic motion of 60 Khz and up to 40 W of power may be utilized to apply ultrasonic motion. Application of the ultrasonic energy enables bonding of the first and the second electrical connections 127 and 129 to the first and second electrical connection pads of the PCB.

FIG. 1E shows the die 110 and the PCB 140 as ultrasonic motion is being applied to the die 110 via the block 160. The direction of motion is depicted by the arrow 160. As seen there, the direction of motion 160 is substantially orthogonal to the direction of the force 157.

In some embodiments, thermosonic bonding, which makes up part of disclosed methods can also be described as follows. The die can be picked up (obtained) and placed on a stage and heated to approximately 150° C. and mechanically clamped. The die could have been picked from a waffle pack or gel pack, for example. The electrical connection bumps can be aligned with the connection bond pads on the PCB. The die can be brought in contact with the PCB and a bond load in the range of 20-80 grams per bump can be applied. Ultrasonic energy can be applied, and the gold bumps are caused to fuse or be bonded to the bonding pads.

In some methods, additional, optional steps may also be carried out. In some embodiments, additional, optional steps may be carried out before disclosed methods. In some embodiments, additional, optional steps may be carried out at some point during disclosed methods. In some embodiments, additional, optional steps may be carried out at some point after disclosed methods.

In some embodiments, for example, the die, the PCB, or both may be cleaned, conditioned, or a combination thereof before any disclosed steps are carried out. In some embodiments, for example, this could include plasma treating the PCB, part of the PCB, the die, part of the die, or a combination thereof prior to contacting the first and the second electrical connection bumps of the die with the first and the second connection pads respectively on the PCB. In some methods, additional steps may be carried out the PCB, part of the PCB, the die, part of the die, or a combination thereof prior to contacting the first and the second electrical connection bumps of the die with the first and the second connection pads respectively on the PCB.

In some embodiments, disclosed methods herein include bonding the first and the second electrical connection bumps of the die with (or to) the first and the second connection pads respectively on the PCB without the use of flux. In some embodiments, disclosed methods herein include bonding the first and the second electrical connection bumps of the die with the first and the second connection pads respectively on the PCB without the use of solder. In some embodiments, disclosed methods herein include bonding the first and the second electrical connection bumps of the die to the first and the second connection pads respectively on the PCB without the use of flux or solder or a combination thereof. In some embodiments, there is no need to wash or subject the assembly to any kind of rinse after the bonds are formed. As such, in some embodiments, the first and the second electrical connection bumps of the die are bonded to the first and the second connection pads respectively on the PCB without the need for an aqueous rinse after bonding.

Also disclosed herein are assemblies. An example of a disclosed assembly is depicted in FIG. 1F, for example. Disclosed assemblies include, for example a die 110 having a first and an opposing second major surface, the die including thereon, therein or some combination thereof a piezoelectric structure 116, a first 118 and a second electrode 120 electrically connected to the piezoelectric structure 116 (which are all part of a BAW resonator) that forms an active surface 125; a printed circuit board (PCB), the PCB having a first major surface and an opposing second major surface and a slot 149 that spans from the first major surface to the second major surface of the PCB; and a first bond 162 electrically and mechanically connecting the die to the PCB; and a second bond 164 electrically and mechanically connecting the die to the PCB. The first and the second bonds 162 and 164 are generally formed by fusing or melding the first and the second electrical connection bumps of the die to the first and the second connection pads of the PCB together. In some embodiments, there can be a delineation between the portions that came from the die and the PCB respectively in one or both the bonds and in some embodiments, there is some delineation between the portions that came from the die and the PCB respectively in one or both the bonds, and in some embodiments, there is no delineation between the portions that came from the die and the PCB respectively in one or both the bonds.

In some embodiments, the first and the second electrical connection bumps in dies can include gold. In some embodiments, the first and the second electrical connection bumps in dies can include multi-layer structures underlying the gold. In some embodiments, the first and the second electrical connection bumps in dies can include gold which is underlaid by a multi-layer structure including a platinum layer and a titanium layer. In some embodiments, the first and the second electrical connection bumps in dies can be formed using physical vapor deposition (PVD), for example.

In some embodiments, the first and the second connection pads in PCBs can include gold. In some embodiments, the first and the second connection pads in PCBs can include gold that is underlaid with layers of nickel, platinum, palladium, alloys, or mixtures thereof. In some embodiments, the first and the second connection pads in PCBs can include multi-layer structures including a gold layer and other metal layers underneath the gold layer. In some embodiments, the first and the second connection pads in PCBs can include multi-layer structures a gold layer a platinum layer and a titanium layer. In some embodiments, the first and the second connection pads in PCBs can be formed using electroless nickel immersion/immersion gold (ENIG), Electroless Nickel Electroless Palladium Immersion Gold (ENEPIG), or electroplated gold.

Electroless nickel immersion/immersion gold (ENIG) has gold deposited directly on top of nickel. ENEPIG is similar to ENIG in that they both utilize electroless nickel on top of copper plating; the difference is while ENIG has gold deposited directly on top of nickel, ENEPIG has an additional layer of palladium between the nickel and final gold layer. ENEPIG is a type of surface plating applied on a printed circuit board to protect it from environmental factors during storage and operation. ENEPIG is prepared by depositing electroless Nickel (Ni 3-5 μm), followed by electroless Palladium (Pd 0.05-0.1 μm), and an immersion gold layer (Au 0.03-0.05 μm).

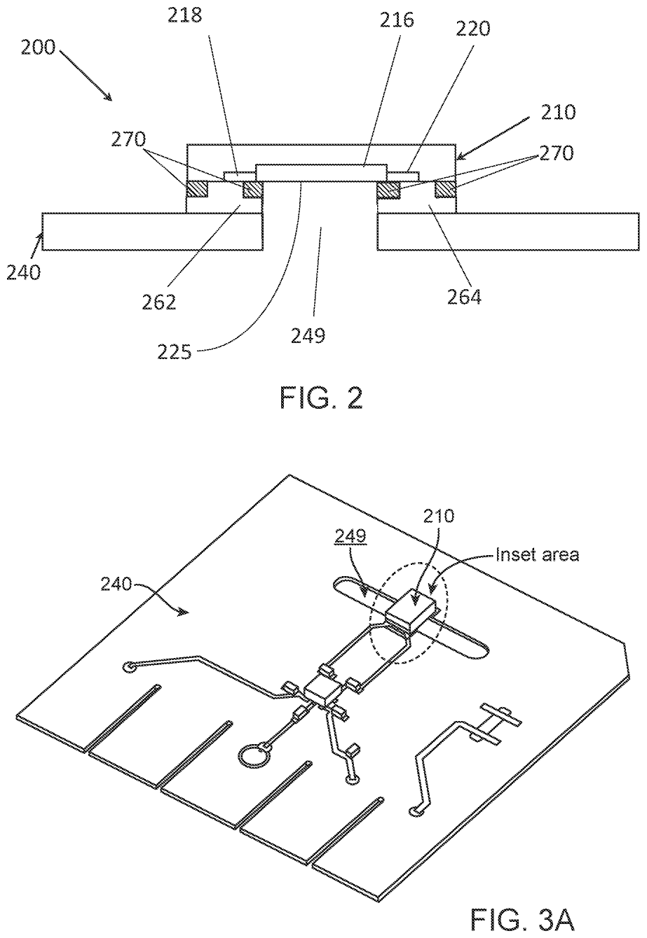

After the first and the second bonds 162 and 164 are formed, additional, optional steps may also be carried out. One specific, optional step that can be carried out is that the bonds may be encapsulated with a dielectric material. This encapsulation can also be referred to as underfill which may help to protect against mechanical strain put on the bonds, reduce thermal mismatch between overlying layers, provide hermetic sealing of bonds from fluids, or combinations thereof. In some embodiments, a polymeric material can be utilized as underfill. In some more specific embodiments, polyimides or epoxies for example may be utilized as underfill material. Underfill material may also more specifically include thermal curing liquid epoxy or snap curing liquid epoxy provided by needle or jet dispenser. The device depicted in FIG. 2 includes underfill 270 regions that bridge the space between the die 210 and the PCB 240 around the first 262 and the second 264 bonds.

Additional other optional steps may also be carried out after the bonds are formed. For example, the assemblies may be subjected to a heat treatment which may be useful for post deposition treatment of some underfill materials.

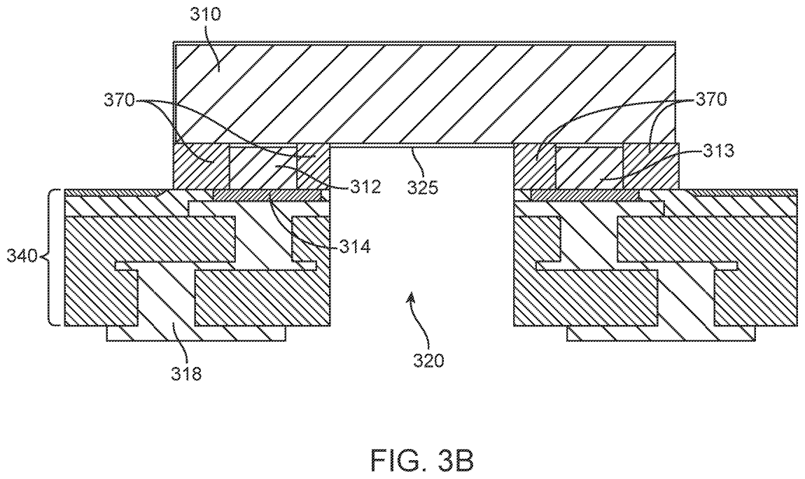

FIG. 3A shows a perspective view of a PCB that includes a bonded die 210 as well as a portion of a fluidic channel of a bioelectronic device that can be made using disclosed assemblies. FIG. 3A shows the slot 249 in the PCB 240 and the die 210. FIG. 3B is a close up view of the die overlying the PCB. In FIG. 3B, the die 310 has a first active surface 325. The die 310 is bonded to the PCB 340 via the first 312 and the second 313 bonds. The first 312 and the second 313 bonds are surrounded by underfill 370 regions. A metallic underlayer 314 is shown under the first 312 bond. In some embodiments, the underlayer 314 can include a nickel layer and optionally additional layers (e.g., a nickel layer and a platinum or palladium layer). Solder pad 318 is shown as being electrically connected to the underlayer 314 and therefore the bond 312, and the die 310 via the electrical properties of all of the materials making up these structures.

The first and the second bonds between the die and the PCB can be characterized based on the mechanical strength of the bonds, for example. In some embodiments, the first and the second bond have a shear force of at least 0.7 kilogram feet (kgf), at least 0.9 kgf, or at least 1 kgf, for example.

The following is a list of exemplary embodiments of the present disclosure.

Example 1 is a method of bonding a bulk acoustic wave sensor die and a printed circuit board, the method comprising: obtaining a die, the die having a first major surface and an opposing second major surface, the die comprising a bulk acoustic wave sensor that comprises a piezoelectric structure electrically connected to a first and a second electrode, the first and the second electrode electrically connected to a first and a second electrical connection bump on the first major surface of the die; obtaining a printed circuit board (PCB), the PCB having a first major surface and an opposing second major surface, the PCB having a slot that spans from the first major surface to the second major surface of the PCB, the first major surface having a first and a second connection pads adjacent to the slot through the PCB; aligning the first and the second electrical connection bumps of the die with the first and the second connection pads respectively on the PCB such that the first surface of the die is above the slot in the PCB; contacting the first and the second electrical connection bumps of the die with the first and the second connection pads of the PCB respectively; heating the die, the PCB, or both; applying a force to the die, the force being applied in the direction of the PCB; and applying ultrasonic energy to the die to bond the first and the second electrical connection bumps of the die with the first and the second connection pads of the PCB respectively.

Example 2 is a method according to Example 1, wherein the first and the second electrical connection bumps of the die comprise gold.

Example 3 is any of the methods according to Examples 1 or 2, wherein the first and the second electrical connection bumps of the die are electrically connected to first and second die electrical connection pads that are electrically connected to the first and second electrodes of the die respectively.

Example 4 is any of the methods according to Examples 1 to 3, wherein the first and the second connection pads of the PCB comprise gold.

Example 5 is any of the methods according to Examples 1 to 4 further comprising plasma treating the PCB, the die, or a combination thereof prior to contacting the first and the second electrical connection bumps of the die with the first and the second connection pads respectively on the PCB.

Example 6 is any of the methods according to Examples 1 to 5 further comprising encapsulating the bonded first and second electrical connection bumps of the die and the first and second connection pads of the PCB respectively with underfilling dielectric material to provide electrical isolation.

Example 7 is any of the methods according to Examples 1 to 6, wherein the first and the second electrical connection bumps of the die are bonded to the first and the second connection pads respectively on the PCB without the use of flux.

Example 8 is any of the methods according to Examples 1 to 7, wherein the first and the second electrical connection bumps of the die are bonded to the first and the second connection pads respectively on the PCB without the use of solder.

Example 9 is any of the methods according to Examples 1 to 8, wherein the first and the second electrical connection bumps of the die are bonded to the first and the second connection pads respectively on the PCB without the need for an aqueous wash and rinse after bonding.

Example 10 is any of the methods according to Examples 1 to 9, wherein the first major surface of the die has an active surface thereon.

Example 11 is any of the methods according to Examples 1 to 3, wherein the die and the PCB are aligned such that the active surface of the die is above the slot in the PCB.

Example 12 is an assembly comprising: a bulk acoustic wave acoustic sensor die having a first and an opposing second major surface, the die comprising a piezoelectric structure, a first and a second electrode electrically connected to the piezoelectric structure, and an active surface on the first major surface of the die; a printed circuit board (PCB), the PCB having a first major surface and an opposing second major surface and comprising: a slot spanning from the first major surface to the second major surface through the PCB; a first bond electrically and mechanically connecting the die to the PCB; and a second bond electrically and mechanically connecting the die to the PCB, wherein the first and the second bonds are located on either side of the slot through the PCB and the active surface of the die is above the slot in the PCB.

Example 13 is the assembly according to Example 12, wherein the first and the second bonds were formed by fusing a first and a second electrical connection bump on the first major surface of the die with first and second electrical connection pads on the first major surface of the PCB.

Example 14 is the assembly according to any of Examples 12 or 13, wherein the first and the second electrodes are electrically and mechanically connected to the first and the second bonds respectively.

Example 15 is the assembly according to any of Examples 12 to 14, wherein the PCB further comprises a metallic underlayer mechanically and electrically connected to the first and the second bonds respectively.

Example 16 is the assembly according to any of Examples 12 to 15, wherein the first and the second electrical connection bumps on the first major surface of the die comprise gold.

Example 17 is the assembly according to any of Examples 12 to 16 further comprising first and second die electrical connection pads wherein the first and second die electrical connection pads are electrically connected to the first and the second electrical connection bumps and the first and second die electrical connection pads comprise gold.

Example 18 is the assembly according to any of Examples 12 to 17, wherein the first and second die electrical connection bumps are placed on the first and second electrical connection pads using a wire bonding process.

Example 19 is the assembly according to any of Examples 12 to 18, wherein first and second electrical connection pads on the PCB are formed using electroless nickel immersion/immersion gold (ENIG), electroless nickel electroless palladium immersion gold (ENEPIG) or electroplated gold.

Example 20 is the assembly according to any of Examples 12 to 19, wherein the first and the second bonds are comprised of gold.

Example 21 is the assembly according to any of Examples 12 to 20, wherein the first and the second bonds do not include any flux, solder, or combinations thereof.

Example 22 is the assembly according to any of Examples 12 to 21, further comprising underfill regions that encapsulate the first and second bonds with dielectric material to provide electrical isolation.

Example 23 is the assembly according to any of Examples 12 to 22, wherein the dielectric material comprises a polymeric material.

Example 24 is the assembly according to any of Examples 12 to 23, wherein the polymeric material comprises a polyimide, an epoxy, or combinations thereof.

All references and publications cited herein are expressly incorporated herein by reference in their entirety into this disclosure, except to the extent they may directly contradict this disclosure. Although specific embodiments have been illustrated and described herein, it will be appreciated by those of ordinary skill in the art that a variety of alternate and/or equivalent implementations can be substituted for the specific embodiments shown and described without departing from the scope of the present disclosure. It should be understood that this disclosure is not intended to be unduly limited by the illustrative embodiments and examples set forth herein and that such examples and embodiments are presented by way of example only with the scope of the disclosure intended to be limited only by the claims set forth here.

1. A method of bonding a bulk acoustic wave sensor die and a printed circuit board, the method comprising:
obtaining a die, the die having a first major surface and an opposing second major surface, the die comprising a bulk acoustic wave sensor that comprises a piezoelectric structure electrically connected to a first and a second electrode, the first and the second electrode electrically connected to a first and a second electrical connection bump on the first major surface of the die;
obtaining a printed circuit board (PCB), the PCB having a first major surface and an opposing second major surface, the PCB having a slot that spans from the first major surface to the second major surface of the PCB, the first major surface having a first and a second connection pads adjacent to the slot through the PCB;
aligning the first and the second electrical connection bumps of the die with the first and the second connection pads respectively on the PCB such that the first surface of the die is above the slot in the PCB;
contacting the first and the second electrical connection bumps of the die with the first and the second connection pads of the PCB respectively;
heating the die, the PCB, or both;
applying a force to the die, the force being applied in the direction of the PCB; and
applying ultrasonic energy to the die to bond the first and the second electrical connection bumps of the die with the first and the second connection pads of the PCB respectively.

2. The method according to claim 1, wherein (i) the first and the second electrical connection bumps of the die, (ii) the first and the second connection pads of the PCB, or both (i) and (ii) comprise gold.

3. The method according to claim 1, wherein the first and the second electrical connection bumps of the die are electrically connected to first and second die electrical connection pads that are electrically connected to the first and second electrodes of the die respectively.

4. (canceled)

5. The method according to claim 1 further comprising plasma treating the PCB, the die, or a combination thereof prior to contacting the first and the second electrical connection bumps of the die with the first and the second connection pads respectively on the PCB.

6. The method according to claim 1 further comprising encapsulating the bonded first and second electrical connection bumps of the die and the first and second connection pads of the PCB respectively with underfilling dielectric material to provide electrical isolation.

7. The method according to claim 1, wherein the first and the second electrical connection bumps of the die are bonded to the first and the second connection pads respectively on the PCB without the use of any flux, solder, or combinations thereof.

8. (canceled)

9. The method according to claim 1, wherein the first and the second electrical connection bumps of the die are bonded to the first and the second connection pads respectively on the PCB without the need for an aqueous wash and rinse after bonding.

10. The method according to claim 1, wherein the first major surface of the die has an active surface thereon.

11. The method according to claim 10, wherein the die and the PCB are aligned such that the active surface of the die is above the slot in the PCB.

12. An assembly comprising:
a bulk acoustic wave acoustic sensor die having a first and an opposing second major surface, the die comprising
a piezoelectric structure,
a first and a second electrode electrically connected to the piezoelectric structure, and
an active surface on the first major surface of the die;
a printed circuit board (PCB), the PCB having a first major surface and an opposing second major surface and comprising:
a slot spanning from the first major surface to the second major surface through the PCB;
a first bond electrically and mechanically connecting the die to the PCB; and
a second bond electrically and mechanically connecting the die to the PCB,
wherein the first and the second bonds are located on either side of the slot through the PCB and the active surface of the die is above the slot in the PCB.

13. The assembly according to claim 12, wherein the first and the second bonds were formed by fusing a first and a second electrical connection bump on the first major surface of the die with first and second electrical connection pads on the first major surface of the PCB.

14. The assembly according to claim 12, wherein the first and the second electrodes are electrically and mechanically connected to the first and the second bonds respectively.

15. The assembly according to claim 12, wherein the PCB further comprises a metallic underlayer mechanically and electrically connected to the first and the second bonds respectively.

16. The assembly according to claim 13, wherein the first and the second electrical connection bumps on the first major surface of the die comprise gold.

17. The assembly according to claim 16 further comprising first and second die electrical connection pads wherein the first and second die electrical connection pads are electrically connected to the first and the second electrical connection bumps and the first and second die electrical connection pads comprise gold

18. The assembly according to claim 17, wherein the first and second die electrical connection bumps are placed on the first and second electrical connection pads using a wire bonding process.

19. The assembly according to claim 13, wherein first and second electrical connection pads on the PCB are formed using electroless nickel immersion/immersion gold (ENIG), electroless nickel electroless palladium immersion gold (ENEPIG) or electroplated gold.

20. The assembly according to claim 12, wherein the first and the second bonds are comprised of gold.

21. The assembly according to claim 12, wherein the first and the second bonds do not include any flux, solder, or combinations thereof.

22. The assembly according to claim 12 further comprising underfill regions that encapsulate the first and second bonds with dielectric material to provide electrical isolation.

23. (canceled)

24. (canceled)
